(19) United States
(12) Patent Application Publication
(10) Pub. No.: US 2026/0293332 A1
(43) Pub. Date: Sep. 24, 2026

(54) PHOTOELECTRIC DEVICE BASED ON QUANTUM DOTS AND ITS MANUFACTURING METHOD

(71) Applicant: University-Industry Cooperation Group of Kyung Hee University, Yongin-si (KR)

(72) Inventors: Seong Jun Kang, Seoul (KR); Jun Hyung Jeong, Suwon-si (KR)

(73) Assignee: University-Industry Cooperation Group of Kyung Hee University, Yongin-si (KR)

(21) Appl. No.: 19/678,506

(22) Filed: May 15, 2026

Related U.S. Application Data
(62) Division of application No. 18/422,928, filed on Jan. 25, 2024.

(30) Foreign Application Priority Data
Jan. 25, 2023 (KR) 10-2023-0009313

(51) Int. Cl. H10F 30/282; B82Y 20/00; B82Y 40/00; C09K 11/88; H10F 71/00; H10F 77/123; H10F 77/14; H10F 77/162

(52) U.S. Cl. CPC H10F 30/282; C09K 11/883; H10F 71/125; H10F 77/123; H10F 77/1433; H10F 77/162; B82Y 20/00; B82Y 40/00

(57) ABSTRACT

A method for manufacturing a photoelectrical device based on quantum dots includes preparing zinc oxide solution and zirconium oxide solution; coating the zinc oxide solution on a substrate to form a zinc oxide layer; coating quantum dots on the zinc oxide layer to form a QDs layer; forming a zirconium oxide layer on the QDs layer; and forming an electrode on the substrate. The zirconium oxide layer is formed through one coating process and two heat treatment processes.

### CROSS-REFERENCE TO RELATED APPLICATION

Priority is claimed on U.S. patent application Ser. No. 18/422,928 filed on Jan. 25, 2024 and Korean Patent Application No. 10-2023-0009313 filed on Jan. 25, 2023, in the Korean Intellectual Property Office, the contents of which are incorporated herein by reference in their entirety.

### BACKGROUND

### 1. Field

The present disclosure relates to a photoelectric device based on quantum dots and its manufacturing method, and in particular to a photoelectric device based on quantum dots with a zirconium oxide (ZrO₂) layer formed on top to protect the quantum dots from the external atmosphere and enhance their photoresponse characteristics, and a manufacturing method thereof.

### 2. Description of Related Art

With the increasing popularity of next-generation wearables and smart electronic devices, research in this field is actively underway, highlighting the importance of studying photoelectric devices such as photo sensors. A photo sensor is a device that absorbs light of various wavelengths and converts it into an electrical signal. For these photo sensors to be used in next-generation electronic devices, high transparency is required.

Traditionally, most photo sensors have used silicon with small band gaps, but this silicon presents an issue in achieving transparency.

To solve this issue, quantum dots, which are nano particles, have been studied in the past since quantum dots offer a wide range of potential, including easy adjustment of band gaps and the ability to be commercialized as photodetectors through solution processes. Korean Patent Publication No. 10-2021-0130596 describes a photo sensor using quantum dots.

However, while quantum dots have the advantage of providing transparency, they have other issues that make it difficult to ensure their stability in the atmosphere. In other words, while quantum dots offer transparency, they face challenges in ensuring stability in the presence of external oxygen and moisture, making it difficult for devices based on quantum dots to operate stably for long periods of time. Of course, previous studies have tried to employ shells and ligands to the core of the quantum dots in order to protect the core, which is less stable in the atmosphere, but the stability in the atmosphere has not been improved due to the properties of quantum dots in the form of nanoparticles.

In addition, the introduction of ligands into quantum dots has presented another issue: reduced photoreactivity resulting from defects induced by the ligands.

### SUMMARY

In one general aspect, a photoelectric device based on quantum dots (QDs) includes a substrate; a zinc oxide layer stacked on the substrate; a quantum dots layer (QDs layer) stacked on the zinc oxide layer; and a zirconium oxide (ZrO2) layer stacked on the QDs layer, enabling stability in atmosphere and eliminating defects caused by ligands of the quantum dots.

The zirconium oxide layer may function as a channel layer and provide a high photosensitivity of 6.67×10⁵ and a photoresponsivity of 0.81 A/W.

The zirconium oxide layer, the zinc oxide layer, and the QDs layer may be formed in order of increasing thickness. The QDs layer may be formed to a thickness of 23 nm, the zinc oxide layer to a thickness of 5 nm or less, and the zirconium oxide layer to a thickness of 4 nm or less.

The zirconium oxide layer may be formed by a spin coating process.

In another general aspect, a method for manufacturing a photoelectrical device based on quantum dots including: preparing zinc oxide solution and zirconium oxide solution; coating the zinc oxide solution on a substrate to form a zinc oxide layer; coating quantum dots on the zinc oxide layer to form a QDs layer; forming a zirconium oxide layer on the QDs layer; and forming an electrode on the substrate. The zirconium oxide layer is formed through one coating process and two heat treatment processes.

the coating process may be performed at a speed of 3000 rpm for 30 seconds, and the heat treatment process includes primary heat treatment at 120° C. for 1 minute followed by secondary heat treatment at 300° C. for 1 minute.

The preparation of the zinc oxide solution may include dissolving 0.08319 g of zinc oxide powder in 12 ml of ammonium hydroxide to prepare a 0.083 M zinc oxide solution, and stirring the prepared zinc oxide solution for 30 minutes and subsequently storing in a refrigerated environment for 5 hours.

The preparation of the zirconium oxide solution may include dissolving 0.3468 g of zirconium oxynitrate (ZrO(NO₃)₂·xH₂O) in 1 ml of deionized water (DI water), sonicating for 30 minutes, adding 10 ml of ethylene glycol monomethyl ether and stirring for 30 minutes, and adding more ethylene glycol monomethyl ether to dilute to a predetermined ratio.

The zinc oxide layer may be formed by spin-coating the zinc oxide solution at a speed of 3000 rpm for 30 seconds and subsequently performing a heat treatment at 300° C. for 60 minutes.

The QDs layer may be formed by spin-coating 20 mg/ml of CdSe/ZnS-based quantum dots at a speed of 2000 rpm for 30 seconds and subsequently performing a heat treatment at 200° C. for 30 minutes.

### BRIEF DESCRIPTION OF THE DRAWINGS

FIG. 1 illustrates a diagram of a photoelectric device based on quantum dots in accordance with an embodiment of the present disclosure.

FIG. 2 illustrates a process flowchart of the manufacturing process of another photoelectric device based on quantum dots in accordance with an embodiment of the present disclosure.

FIG. 3 illustrates a diagram that compares the photo transmittance between a conventional photoelectric device and the photoelectric device of the present disclosure.

FIG. 4 illustrates a diagram showing a transfer curve between a conventional photoelectric device and the photoelectric device of the present disclosure.

FIG. 5 illustrates a graph that compares the V_{T} shift values between a conventional photoelectric device and the photoelectric device of the present disclosure.

FIG. 6 illustrates a graph showing the photoresponsivity between a conventional photoelectric device and the photoelectric device of the present disclosure.

FIG. 7 illustrates a graph showing the photosensitivity between a conventional photoelectric device and the photoelectric device of the present disclosure.

FIG. 8 illustrates a graph of the stability between a conventional photoelectric device and the photoelectric device of the present disclosure.

FIG. 9 illustrates a transfer curve graph comparing a conventional photoelectric device and the photoelectric device according to the present disclosure, measured immediately after manufacturing and again after 30 days.

### DETAILED DESCRIPTION

This invention is capable of various modifications and can have several embodiments, therefore, specific embodiments are illustrated in the drawings and described in detail. However, this is not intended to limit the invention to any particular embodiment, and is to be understood to include all modifications, equivalents or substitutions that fall within the scope of the thought and skill of the present disclosure. In describing the invention, where it is believed that a detailed description of the relevant prior art would obscure the gist of the invention, such detailed description is omitted.

Terms such as first, second, and the like may be used to describe various components, but the components shall not be limited by such terms. These terms are used only for the purpose of distinguishing one component from another.

The terminology used in the present disclosure is intended to describe particular embodiments only and is not intended to limit the invention. Expressions in the singular include the plural unless the context clearly indicates otherwise. In this application, terms such as “includes” or “has” are intended to designate the presence of the features, numbers, steps, actions, components, parts, or combinations thereof described in the specification, not the presence of one or more other features, numbers, steps, actions, components, or combinations thereof.

The spatially relative terms below, beneath, lower, above, upper, and the like may be used to facilitate the description of the relationship of one element or component to another element or component as shown in the drawings. Spatially relative terms should be understood to include different orientations of an element in use or operation in addition to the orientations shown in the drawings. For example, an element described as being below or beneath another element may be placed above or above another element when the elements shown in the drawing are inverted. Thus, the exemplary term below may include both below and above orientations. Elements may also be orientated in other directions, and accordingly, spatially relative terms may be interpreted according to their orientation.

Accordingly, the idea of the invention is not to be limited to the embodiments described, and it will be understood that the following patent claims, as well as all equivalents or equivalent variations thereof, fall within the scope of the idea of the invention.

The present disclosure is designed to solve the above problems, and provides a quantum dot-based photoelectric device and a method for manufacturing the same, which enables the quantum dot-based photoelectric device to operate stably for a long period of time, and further prevents defects caused by ligands.

The technical challenges of the present disclosure are not limited to the technical challenges mentioned above, and other technical challenges not mentioned will be apparent to those skilled in the art from the following description.

In the following, the invention will be described in more detail with reference to the embodiments shown in the drawings.

A photoelectric device 100 according to an embodiment of the present disclosure may be a photodetector, such as a photodiode, photoresistor, phototransistor, etc. A phototransistor is a device that can control a wide range of photo currents by adjusting the gate voltage and the drain voltage.

The photoelectric device 100 based on quantum dots according to an example of the present disclosure is characterized by being formed through the sequential stacking of zirconium oxide (ZrO₂) onto zinc oxide (ZnO)/quantum dots (QDs) treated with a solution. Through the zirconium oxide, quantum dots can be protected and stability can be achieved. Additionally, the photodetector with added zirconium oxide (ZrO₂) can provide a high photosensitivity of 6.67×10⁵ and a photoresponsivity of 0.81 A/W by serving as the channel layer.

The photoelectric device based on quantum dots with these technical features will be discussed in detail.

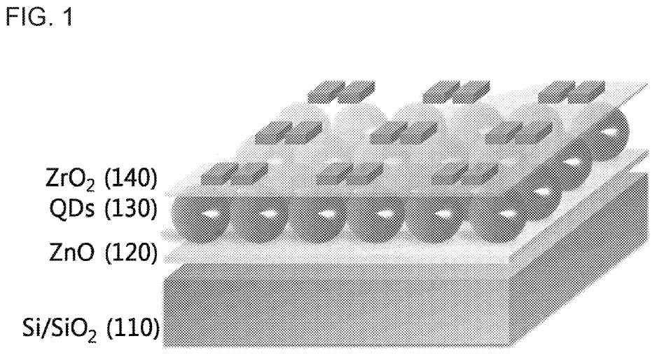

FIG. 1 illustrates a diagram of a photoelectric device based on quantum dots in accordance with an embodiment of the present disclosure.

Referring to FIG. 1, a photoelectric device 100 based on quantum dots according to the present disclosure includes a substrate 110, a zinc oxide layer 120, a layer of quantum dots (QDs) (hereinafter referred to as “QDs layer”) 130, and a zirconium oxide (ZrO₂) layer 140.

The substrate 110 may have a structure with a gate terminal formed at the bottom and a thin-film transistor (TFT) formed at the top. The substrate 110 may be formed of materials such as silicon (Si) or silicon oxide (SiO₂). However, in addition to these materials, various other materials may be adopted for constructing the photoelectric device.

The substrate 110 features a structure where zinc oxide (ZnO) 120, quantum dots (QDs) 130, and zirconium oxide (ZrO₂) 140 are stacked. In an embodiment, the thickness of the zinc oxide (ZnO) layer 120 and the QDs layer 130 may be formed to be 5 nm or less and 23 nm, respectively. In addition, the zirconium oxide layer 140 deposited on top of the quantum dot layer 130 may be formed by deposition to a thickness of about 4 nm or less, for example, via a spin coating process. Since zirconium oxide can be formed on top of the quantum dot layer 130 with a predetermined thickness through a solution process, manufacturing time and costs can be reduced compared to general methods such as vacuum deposition, atomic layer deposition, and sputtering.

The surface roughness was reduced by the formation of zirconium oxide (ZrO₂) 140 stacked on top of the quantum dot layer 130. In other words, through experimentation, it was observed that the surface roughness of quantum dots was decreased from 3.32 nm for the original quantum dots to 2.72 nm with the formation of zirconium oxide (ZrO₂). Consequently, an improvement in electrical characteristics was achieved. In embodiments, roughness can be confirmed using Atomic Force Microscopy (AFM) measurement images.

Specifically, it was confirmed that the photoelectric device with the conventional structure of zinc oxide (ZnO) 120/quantum dots (QDs) 130 experienced degradation in electrical characteristics due to its high surface roughness, whereas the photoelectric device with the structure of zinc oxide (ZnO) 120/quantum dots (QDs) 130/zirconium oxide (ZrO₂) 140, incorporating ZrO₂, exhibited improved electrical characteristics. This improvement could be attributed to the reduction in surface roughness.

The root mean square values of the surface roughness of the photoelectric device with the following structures: zinc oxide (ZnO); zinc oxide (ZnO) 120/quantum dots (QDs) 130; and zinc oxide (ZnO) 120/quantum dots (QDs) 130/zirconium oxide (ZrO₂) 140, were determined using the AFM measurement images as described above. The addition of ZrO₂ resulted in a decrease in surface roughness from 3.32 to 2.72 nm, contributing the enhanced electrical characteristics.

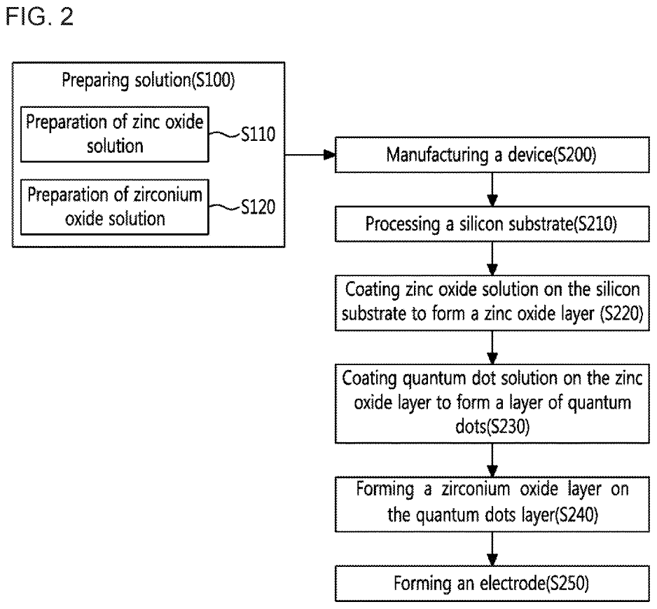

FIG. 2 illustrates a process flowchart of the manufacturing process of another photoelectric device based on quantum dots in accordance with an embodiment of the present disclosure.

The manufacturing process in accordance with embodiments of the present disclosure can be broadly categorized into solution preparation S100 and device manufacturing S200.

### Solution Preparation (S100)

In solution preparation, solutions of zinc oxide (ZnO) and zirconium oxide (ZrO₂) can be prepared.

Firstly, it is the process of preparing zinc oxide (ZnO) solution (S110).

12 ml of ammonium hydroxide is dissolved with 0.08319 g of zinc oxide (ZnO) powder to prepare a 0.083 M zinc oxide solution. After stirring the prepared zinc oxide solution for 30 minutes, it is stored in a refrigerated environment for 5 hours to increase solubility.

Secondly, it is the process of preparing zirconium oxide (ZrO₂) solution (S120).

0.3468 g of zirconium oxynitrate (ZrO(NO₃)₂·xH₂O) is dissolved in 1 ml of deionized (DI) water, followed by sonication for 30 minutes. This process results in the preparation of a uniform and transparent solution.

After sonication, 10 ml of ethylene glycol monomethyl ether is added and stirred for 30 minutes. Subsequently, additional ethylene glycol monomethyl ether is added to the solution to dilute the solution to concentrations of 0.01 M, 0.03 M, 0.05 M and 0.1 M. The purpose for diluting zirconium oxide (ZrO₂) to concentrations of 0.01 M, 0.03 M, 0.05 M, and 0.1 M is to compare the properties of the zirconium oxide (ZrO₂) at different concentrations.

### Device Manufacturing (S200)

The silicon substrate to be used in various devices, such as photoelectric devices, may be a boron-doped substrate with a silicon dioxide (SiO₂) layer of 100 nm thickness, which may be used as a gate electrode and a gate dielectric.

The silicon substrate is sonicated in deionized (DI) water, acetone, and 2-propanol (IPA) for 15 minutes each. Subsequently, nitrogen gas is blown onto the silicon substrate, followed by treatment with UV ozone for 15 minutes to remove any residual organic impurities remaining on the silicon substrate, resulting in a hydrophilic surface (S210).

Then, the zinc oxide (ZnO) solution prepared in the aforementioned solution preparation process is spin-coated onto the silicon substrate at a speed of 3000 rpm for 30 seconds, followed by heat treatment at 300° C. for 60 minutes to form a zinc oxide layer (ZnO layer) (S220).

Then, quantum dots based on CdSe/ZnS (20 mg/ml, Uniam) are spin-coated on the ZnO layer at 2000 rpm for 30 seconds, followed by heat treatment at 200° C. for 30 minutes to form a quantum dot layer (QDs layer) (S230).

The ZnO layer and the QDs layer are sequentially formed, and then the ZrO₂ layer is formed on the QDs layer. The ZrO₂ layer is formed by spin coating the ZrO₂ solution prepared in the aforementioned solution preparation process onto the QDs layer at a speed of 3000 rpm for 30 seconds, followed by primary heat treatment at 120° C. for 1 minute and secondary heat treatment at 300° C. for 1 minute (S240).

In this way, by forming a ZrO₂ layer on top of quantum dots, which are nanoparticles, it is possible to protect the quantum dots from the external atmosphere and also solve the issue of reduced photoreactivity caused by the ligands that traditionally applied to protect the core of the quantum dots.

Finally, electrodes are formed (S250). In embodiments, the formation of electrodes involves creating source and drain electrodes with a thickness of 100 nm using a metal shadow mask with channel lengths and widths of 100 μm and 1000 μm, respectively. Source and drain electrodes may be formed by thermal evaporation at a ratio of 3 A/S under a pressure of 5×10⁻⁶ torr.

In the following, the characteristics of the photoelectric device based on quantum dots according to the present disclosure will be discussed.

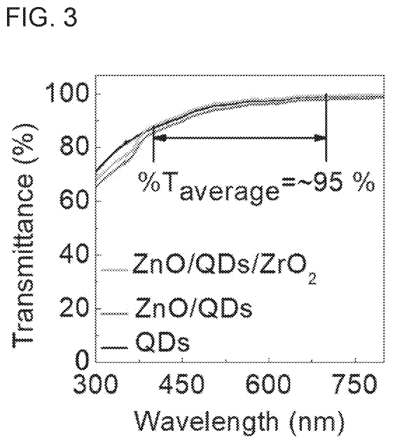

FIG. 3 illustrates a diagram comparing the photo transmittance between a conventional photoelectric device and the photoelectric device of the present disclosure.

It can be seen that the structure with stacked zirconium oxide (ZrO₂) in the present disclosure (ZnO/QDs/ZrO₂) exhibits higher photo transmittance compared to the structures without zirconium oxide (i.e., QDs or ZnO/QDs). The structure of ZnO/QDs/ZrO₂ exhibits a high transmittance of over 95% in the visible light region. Photoelectric devices require high transparency in the visible light range, and being able to provide over 95% transmittance may mean that it is sufficient for functioning as a photoelectric device.

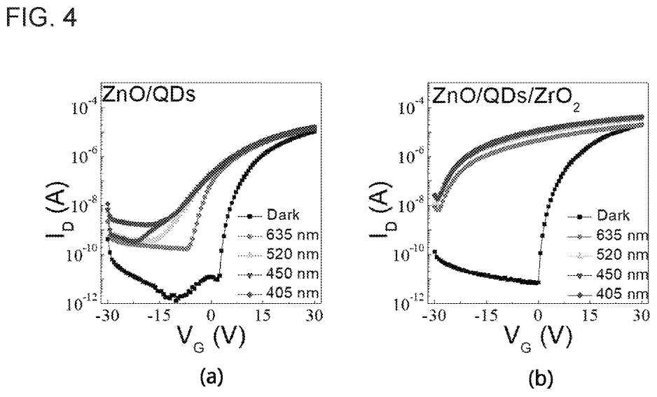

FIG. 4 illustrates a diagram showing a transfer curve between a conventional photoelectric device and the photoelectric device according to the present disclosure. The transfer curve is a graph measured under light illumination conditions with a power density of ~4.5 mW/cm². Comparing the photoelectric device of the conventional structure of ZnO/QDs of the photoelectric device with the structure of ZnO/QDs/ZrO₂ of the photoelectric device according to the present disclosure, it can be seen that the structure of the present disclosure exhibits improved photoresponse characteristics at a wavelength of 635 nm.

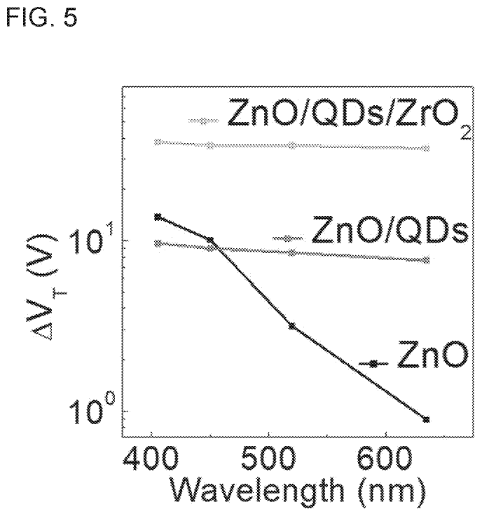

FIG. 5 illustrates a graph comparing the V_{T} shift values between a conventional photoelectric device and the photoelectric device according to the present disclosure. Referring to the graph, it can be seen that in the 635 nm wavelength range, the photoelectric device with the ZnO structure exhibits 1.29 V, the photoelectric device with the ZnO/QDs structure exhibits 7.48 V, while the photoelectric device with the ZnO/QDs/ZrO₂ structure exhibits 37.07 V, indicating the highest amount of photocurrent generation.

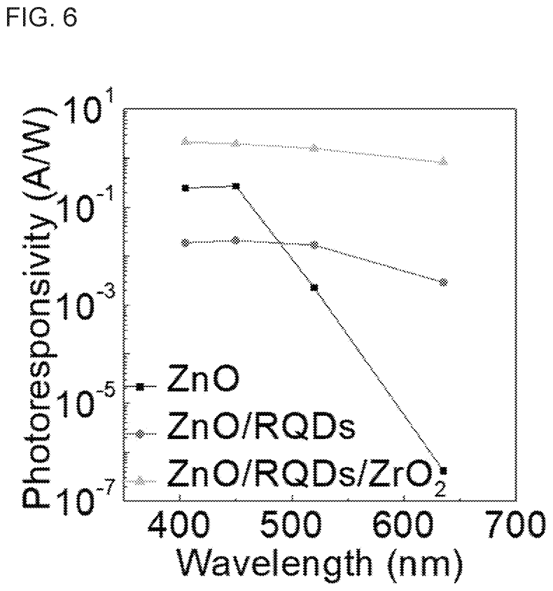

FIG. 6 illustrates a graph showing the photoresponsivity between a conventional photoelectric device and the photoelectric device according to the present disclosure.

Referring to FIG. 6, the photoresponsivity of photoelectric devices with the structures of ZnO, ZnO/QDs, and ZnO/QDs/ZrO₂ at wavelengths of 635 nm, 520 nm, 450 nm, and 405 nm under a power density of 4.5 mW/cm² is calculated using Equation 1.

$$Photoresponsivity = \frac{( {I}_{light} - {I}_{dark} ) / {A}_{pt}}{P / {A}_{pd}} = \frac{{I}_{ph}}{P} \qquad Equation 1$$

Here, I_{light} represents the current under light illumination, I_{dark} represents the current under dark conditions, Aₚₜ represents the product of channel width and thickness, P represents the incident light power density, A_{pd} represents the spot size of the laser source, Jₚₕ represents the photocurrent density, and V_{G} is set to −3 V.

According to the calculation results obtained from Equation 1, the photoresponsivity of the photoelectric device with a ZnO structure is negligible at the 635 nm wavelength range, but it begins to increase at the 520 nm wavelength range. The photoelectric device with a ZnO/QDs structure exhibits a reliable photoresponsivity of 0.003 A/W at the 635 nm wavelength range. In contrast, the photoelectric device with the ZnO/QDs/ZrO₂ structure according to the present disclosure is calculated to have a photoresponsivity of 0.81 A/W at the 635 nm wavelength range. It can be confirmed that the structure according to the present disclosure exhibits a higher photoresponsivity compared to the conventional structure.

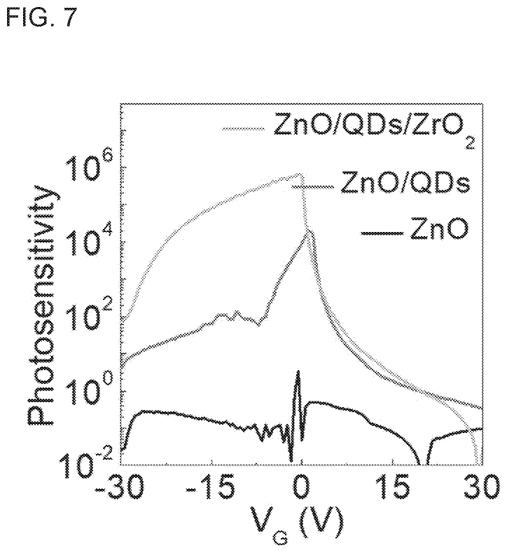

FIG. 7 illustrates a graph showing the photosensitivity between a conventional photoelectric device and the photoelectric device according to the present disclosure.

The photosensitivity serves as an indicator representing the ratio of photocurrent to dark current. The photosensitivity of photoelectric devices with structures of ZnO, ZnO/QDs, and ZnO/QDs/ZrO₂ at the 635 nm wavelength range was calculated using Equation 2.

$$Photosensitivity = ( {I}_{photo} - {I}_{dark} ) / {I}_{dark} \qquad Equation 2$$

Here, Iₚₕₒₜₒ and I_{dark} indicate the current with and without light illumination, respectively.

According to the calculation results obtained from Equation 2, the photosensitivity of the photoelectric device with a ZnO structure exhibits almost negligible levels, while the photoelectric device with a ZnO/QDs/ZrO₂ structure exhibited a significantly high photoresponsivity of 6.67×10⁵.

The following Table 1 shows the V_{T} shift values, photoresponsivity, and photosensitivity for each respective structure.

TABLE 1

| | | Photo- | |
|---|---|---|---|
| | V_{T} | responsivity | Photo- |
| Structure | shift [V] | [A/W] | sensitivity |
| ZnO | 0.89 | 4.2 × 10⁻⁷ | 3.4 |
| ZnO/QDs | 7.65 | 0.003 | 1.97 × 10⁴ |
| ZnO/QDs/ | 34.85 | 0.81 | 6.67 × 10⁵ |
| ZrO₂ | | | |

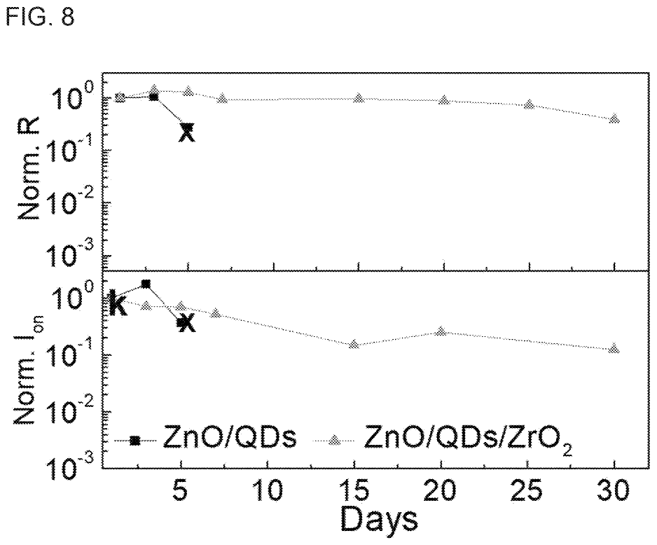

FIG. 8 illustrates a graph showing the stability between a conventional photoelectric device and the photoelectric device according to the present disclosure. Stability is an indicator used to assess whether electrical characteristics and photoresponse characteristics persist even after a predetermined time period.

Experiment of FIG. 8 was conducted under conditions of 40% or less relative humidity to test durability. From this, it can be seen that the conventional photoelectric device with a ZnO/QDs structure, lacking the ZrO₂ layer, exhibited electrical and photoresponse characteristics for about 5 days, whereas the photoelectric device with the ZnO/QDs/ZrO₂ structure according to the present disclosure sustained electrical and photoresponse characteristics for up to about 30 days. This demonstrates its stability over a longer period of time.

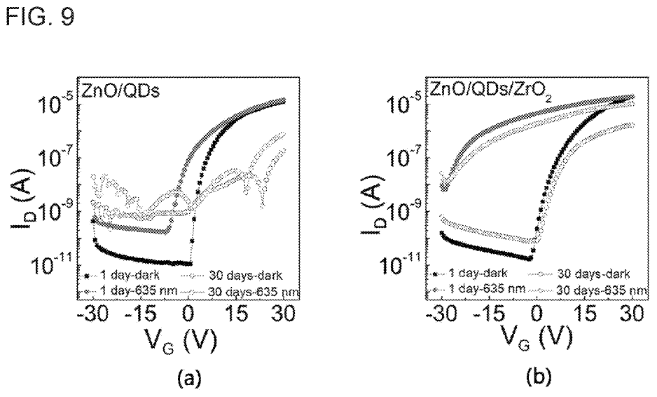

FIG. 9 illustrates a transfer curve graph of a conventional photoelectric device and the photoelectric device according to the present disclosure, measured immediately after manufacturing and again after 30 days.

As illustrated, by examining the transfer curve measured immediately after manufacturing and again after 30 days, it can be confirmed that the photoelectric device with the ZnO/QDs/ZrO₂ structure according to the present disclosure is more stable due to the inclusion of ZrO₂.

the inclusion of ZrO₂ in the ZnO/QDs/ZrO₂ structure of the photoelectric device of the present disclosure contributes to enhanced stability.

Meanwhile, Table 2 compares the electrical characteristics of the conventional structure with those of the structure according to the present disclosure.

TABLE 2

| | μsat | | S/S | VT |
|---|---|---|---|---|
| structure | [cm²/V · s] | Iₒₙ/I_{off} | [V/decade] | [V] |
| ZnO | 0.27 | 2.67 × 10⁶ | 0.095 | 5.96 |
| ZnO/QDs | 0.13 | 8.11 × 10⁵ | 0.196 | 7.4 |
| ZnO/QDs/ | 0.19 | 2.06 × 10⁴ | 0.432 | 5.56 |
| ZrO₂(0.01M) | | | | |
| ZnO/QDs/ | 0.20 | 2.73 × 10⁶ | 0.091 | 6.05 |
| ZrO₂(0.03M) | | | | |
| ZnO/QDs/ | 0.04 | 3.97 × 10⁵ | 0.200 | 6.42 |
| ZrO₂(0.05M) | | | | |
| ZnO/QDs/ | — | — | — | — |
| ZrO₂(0.1M) | | | | |

As described above, it can be seen that a photoelectric device is designed by stacking a ZrO₂ layer, prepared using solution processing, on top of the ZnO/QDs layer, where the ZrO₂ layer serves as a channel layer, can protect the quantum dots from the atmosphere, and ensures the long-term stable operation of the device.

Moreover, the photoelectric device according to the present disclosure can be utilized in various technical fields. For example, it can be widely applied to transparent electronic devices, optical sensors for smart glasses, transparent electronic devices for full-color CCDs, transparent sensors for smart windows, vehicles, and wearable electronic devices, etc., so the industrial availability is very high.

According to the present disclosure, a photoelectric device where zirconium oxide is formed on top of quantum dots through a solution process is proposed. As a result, it ensures high stability in the atmosphere and offers the advantage of securing excellent photoresponse by resolving the conventional defects caused by ligands when ligands were applied to quantum dots for stability in the atmosphere.

According to the present disclosure, there is an expected effect of enabling the development of transparent optical sensors capable of absorbing visible light and converting it into electrical signals.

According to the present disclosure, there is an expected effect of enhancing added value, as it can be applied to various industries such as smart electronic devices, wearable electronic devices, and smart vehicles.

Although the description is made with reference to the illustrated embodiments of the present disclosure as described above, these are merely illustrative, and those of ordinary skill in the art to which the present disclosure pertains will clearly appreciate that various modifications, changes, and other equal embodiments are possible without departing from the gist and scope of the present disclosure. Therefore, the true scope of technical protection of the present disclosure should be determined by the technical idea of the appended claims.

What is claimed is:

1. A method for manufacturing a photoelectrical device based on quantum dots, comprising:
preparing zinc oxide solution and zirconium oxide solution;
coating the zinc oxide solution on a substrate to form a zinc oxide layer;
coating quantum dots on the zinc oxide layer to form a QDs layer;
forming a zirconium oxide layer on the QDs layer; and
forming an electrode on the substrate,
wherein the zirconium oxide layer is formed through one coating process and two heat treatment processes.

2. The method of claim 1,
wherein the coating process is performed at a speed of 3000 rpm for 30 seconds, and the heat treatment process includes primary heat treatment at 120° C. for 1 minute followed by secondary heat treatment at 300° C. for 1 minute.

3. The method of claim 1,
wherein the preparation of the zinc oxide solution comprises dissolving 0.08319 g of zinc oxide powder in 12 ml of ammonium hydroxide to prepare a 0.083 M zinc oxide solution, and stirring the prepared zinc oxide solution for 30 minutes and subsequently storing in a refrigerated environment for 5 hours.

4. The method of claim 1,
wherein the preparation of the zirconium oxide solution comprises dissolving 0.3468 g of zirconium oxynitrate (ZrO(NO₃)₂·xH₂O) in 1 ml of deionized water (DI water), sonicating for 30 minutes, adding 10 ml of ethylene glycol monomethyl ether and stirring for 30 minutes, and adding more ethylene glycol monomethyl ether to dilute to a predetermined ratio.

5. The method of claim 1,
wherein the zinc oxide layer is formed by spin-coating the zinc oxide solution at a speed of 3000 rpm for 30 seconds and subsequently performing a heat treatment at 300° C. for 60 minutes.

6. The method of claim 1,
wherein the QDs layer is formed by spin-coating 20 mg/ml of CdSe/ZnS-based quantum dots at a speed of 2000 rpm for 30 seconds and subsequently performing a heat treatment at 200° C. for 30 minutes.
